(19) United States
(12) Patent Application Publication
(10) Pub. No.: US 2025/0164442 A1
(43) Pub. Date: May 22, 2025

(54) LATERAL AND VERTICAL DIELECTROPHORESIS METHOD FOR MICRO/NANO-SCALE BIOLOGICAL AND METABOLIC SENSORS AND ACTUATORS USING TWO HIGH-INTENSITY ELECTRIC FIELDS

(71) Applicant: ZHEJIANG NORMAL UNIVERSITY, Jinhua (CN)

(72) Inventors: CLARENCE AUGUSTINE TECK HUO TEE, Jinhua (CN); BURHANUDDIN YEOP MAJLIS, Selangor (MY); MUHAMAD RAMDZAN BUYONG, Selangor (MY); WEY PING YEO, Selangor (MY)

(21) Appl. No.: 18/990,730

(22) Filed: Dec. 20, 2024

Related U.S. Application Data
(63) Continuation of application No. PCT/CN2024/087458, filed on Apr. 12, 2024.

(30) Foreign Application Priority Data
Nov. 22, 2023 (CN) 202311565061.8

(51) Int. Cl. G01N 27/447; B01L 3/00; B03C 5/00; H01J 37/32

(52) U.S. Cl. CPC G01N 27/44791; B01L 3/502761; B03C 5/005; H01J 37/321; B01L 2200/0652; B01L 2300/0645; B01L 2300/0858; B01L 2400/0424; B03C 2201/26; H01J 2237/334

(57) ABSTRACT

Disclosed is a lateral and vertical dielectrophoresis method for micro/nano-scale biological and metabolic sensors and actuators using two high-intensity electric fields, including: S1. performing resist plasma etching before metal etching to form a resist profile at a sidewall, where a high-pressure baseline formulation includes oxygen, nitrogen and argon in a ratio of 1:4:140, with a pressure of 1600 mT, and an RF power of 1300 W, which is used to produce a pre-designed angle resist; S2. performing metal etching, a baseline instruction includes chlorine, boron trichloride, and argon, with a preferred ratio of 1:0.4:0.2, a pressure of 8 mT, a source power of preferably 1200 W, and a bias power of preferably 175 W; and S3. performing metal profiling measurement to measure a remaining thickness. The method enables manipulation, separation, and fractionation of target and non-target particles in the medium through lateral positive dielectrophoresis attractive force at Y.

### CROSS-REFERENCE TO RELATED APPLICATIONS

This application is a continuation of International Application No. PCT/CN2024/087458, filed on Apr. 12, 2024, which claims priority to Chinese Patent Application No. 202311565061.8, filed with the China National Intellectual Property Administration on Nov. 22, 2023. Both of which are hereby incorporated by reference in their entireties.

### TECHNICAL FIELD

The present disclosure relates to the technical field of micro/nano-organisms and metabolites thereof, and particularly relates to a lateral and vertical dielectrophoresis method for micro/nano-scale biological and metabolic sensors and actuators using two high-intensity electric fields.

### BACKGROUND

Dielectrophoresis (DEP) is a technique for particle manipulation using dielectric properties of particles. For the technique, sinusoidal time-varying and spatially non-uniform electric fields are used to manipulate positions of particles based on dielectric properties of the particles. DEP can focus, translate and capture, as well as characterize, purify and enrich various material (such as environmental, biological, and clinical analytes) in a fluid suspension medium.

By integrating dielectrophoresis microelectrodes into a lab-on-chip system, the development of non-contact, label-free, and label-free manipulation research further unveils the potential application of DEP in a micro/nano-scale machine. Indirect physical contact or non-contact particle motion can be extensively applied in areas such as drug discovery and delivery, disease screening, separation, and analysis of biological samples, which is mainly because indirect physical contact motion, compared with direct physical contact, can eliminate any potential contact damage and associated problems.

In fact, it becomes increasingly challenging when a moving object is a few micrometer or nanometer in size, which cannot be handled through direct physical contact. Therefore, the advantage of the non-contact particle manipulation method is that an impact caused by physical contact can be eliminated. For the reasons, particle motion facilitated by indirect physical contact through dielectrophoretic properties has been proposed. Other techniques, such as fuorescence-activated cell sorting (FACS), magnetic-activated cell sorting (MACS), and field-flow fractionation (FFF), can also be used for the motion and separation of particles, especially cells. However, DEP-based particle and cell separation which uses force of dielectric polarization (FDEP) exhibits better reliability and performance in terms of sensitivity and selectivity.

### TECHNICAL PROBLEMS

Most designs and research of dielectrophoresis (DEP) electrodes on the market focus on electrodes with higher field intensity at a single point. Therefore, a dielectrophoresis microelectrode with a higher field intensity at one point generates a higher electric field gradient only at a top edge of the microelectrode, which results in low efficiency in the manipulation, separation, and fractionation of target particles in a medium through vertical attractive force and repulsive force of the target's negative dielectrophoresis (NDEP) and positive dielectrophoresis (PDEP). However, less attention has been paid to points of two higher-intensity electric fields in the dielectrophoresis microelectrodes, which could generate lateral and vertical motions of target or non-target particles through uniform and directed DEP force.

In view of the foregoing deficiencies, it is necessary to provide a method for performing lateral and vertical separation of particles using points of two higher-intensity electric fields.

### SUMMARY

### Technical Solution

In order to overcome technical defects in the prior art, the present disclosure provides a lateral and vertical dielectrophoresis (DEP) method for micro/nano-scale biological and metabolic sensors and actuators using two high-intensity electric fields. The method enables more efficient manipulation, separation, and fractionation of target and non-target particles in the medium through lateral positive dielectrophoresis (PDEP) attractive force at Y, and negative dielectrophoresis (NDEP) repulsive force in a vertical direction of a Z axis. A technical solution adopted by the present disclosure for solving the above

technical problems is as follows:

a lateral and vertical dielectrophoresis method for micro/nano-scale biological and metabolic sensors and actuators using two high-intensity electric fields, roughly including: addition steps of SiO2, Ti/TiN and Al/Si/Cu, photolithography steps of coating, exposure, and development of a photoresist, steps of removing a photoresist profile by lateral etching to achieve photoresist bevel, metal etching, and photoresist removal.

The method specifically includes the following steps:

S1. performing resist plasma etching before metal etching to form a resist profile at a sidewall, where a high-pressure baseline formulation includes oxygen (O2), nitrogen (N2), and argon (Ar) in a ratio of 1:4:140, with a pressure of 1600 mT, and an RF power of 1300 W, which is used to produce a pre-designed angle resist;

S2. performing metal etching, a baseline instruction includes chlorine (Cl2), boron trichloride (BCl3), and argon (Ar), with a preferred ratio of, but not limited to, 1:0.4:0.2, a pressure of 8 mT, a source power of preferably 1200 W, and a bias power of preferably 175 W;

S3. performing metal profiling measurement to measure a remaining thickness;

where an inductively coupled plasma (ICP) process based on chemical and physical etching mechanisms is introduced, and new four-step etching technique conditions are introduced to control etching quality;

the four-step etching technique conditions include:

breakthrough etching (BE) controlled by time;

main etching (ME) controlled by endpoint detection;

over-etching (OE) controlled by time of an etching process; and

residue removal etching (RRE) controlled by the time of an etching process.

Preferably, O2 is a primary gas for resist etching, N2 is a buffer gas to maintain a higher chamber pressure, and Ar is used to increase a plasma density.

Preferably, Cl2 is a chlorine-based gas and is used as a primary etchant for plasma-free aluminum, and Cl2 is also a primary etchant for resist.

Preferably, the BE is performed to remove native oxide and resist residues left

after a photolithography process.

Preferably, the ME is performed to remove bulk aluminum.

Preferably, the OE and the RRE are performed to remove residual aluminum on thicker areas of aluminum and to remove aluminum residues.

Preferably, timing of the BE, OE, and RRE is selected on the basis of visual inspection through a microscope for color monitoring, a critical dimension scanning electron microscope (CDSEM) for critical dimension measurement, and a field emission scanning electron microscope (FESEM) for cross-sectional views.

Preferably, the method further uses a microfluidic channel (left, right and middle microfluidic channel) with one input end and three outlet ends to separate target particles and non-target particles to two different locations, that is, a top electrode surface, and between two tapered electrodes.

Preferably, the method involves lateral separation of DEP force, where the lateral separation of DEP force is PDEP attractive force between the two tapered electrodes and the top electrode surface along a Y axis, and a separation yield of particles synchronized with lateral motion to terminal ends of electrodes (terminal ends of the left and right microfluidic channels) along an X axis.

Preferably, the method further includes vertical separation of DEP force, where the vertical separation of DEP force is negative NDEP repulsive force between the two tapered electrodes and the top electrode surface along the X axis, and a separation yield of particles synchronized with vertical motion (terminal ends of the middle microfluidic channel) along the X axis.

Preferably, the two high-intensity electric fields provide separation and fractionation of target and non-target particles in a medium through the PDEP attractive force on the Y axis and the NDEP repulsive force on the Z axis, and collect the flow of one inlet microfluidic channel with three outlet microfluidic channels using capillary force on the X axis.

### Beneficial Effects

Compared with the prior art, the present disclosure has the following beneficial effects: the lateral and vertical dielectrophoresis method for micro/nano-scale biological and metabolic sensors and actuators using two high-intensity electric fields provides dielectrophoresis microelectrodes of two-point higher-intensity electric field to produce a higher electric field gradient from the top and bottom edges of the microelectrodes, such that more efficient manipulation, separation, and fractionation of target and non-target particles are achieved in the medium through the PDEP attractive force in a lateral direction of the Y axis, and the NDEP repulsive force in a vertical direction of the Z axis.

Furthermore, the method can collect the flow of one inlet microfluidic channel with three outlet microfluidic channels using capillary force on the X axis.

### BRIEF DESCRIPTION OF DRAWINGS

FIGS. 1-7 are schematic diagrams of working principles of lateral and vertical dielectrophoretic particle separation using points of two higher-intensity electric fields according to the present disclosure.

FIGS. 8(a-i) are schematic diagrams of fabrication steps of a microelectrode array for dielectrophoresis (DEP)-based application according to the present disclosure.

FIG. 9 is a schematic diagram of a resist angle of about 16-20 degrees produced by lateral etching used for a resist bevel process according to the present disclosure.

FIG. 10 is a schematic diagram after aluminum etching process is performed according to the present disclosure, resulting in an aluminum tilt angle of about 65-70 degrees.

### DESCRIPTION OF EMBODIMENTS

A lateral and vertical dielectrophoresis method for micro/nano-scale biological and metabolic sensors and actuators using two high-intensity electric fields is a new structure of a microelectrode array with points of two higher-intensity electric fields for dielectrophoresis (DEP)-based particle manipulation. The microelectrode array is fabricated using complementary metal-oxide-semiconductor (CMOS) processing technology, and adopts the most advanced technology and metal etching process to form a bevel profile of the resist. The introduced structure demonstrates a more efficient electric field gradient and asymmetric distribution of the electric field, and is used for particle manipulation, separation, and fractionation in both lateral and vertical directions. In addition, two points of a high-intensity electric field with a sidewall profile angle of 20° produce a higher electric field gradient from the top and bottom edges of the microelectrode based on field analysis, such that more efficient operation, separation and fractionation can be achieved.

Therefore, target or non-target particles are separated at two different locations, that is, a top electrode surface and between two tapered electrodes. Separation occurs at the top of the electrodes due to the lateral attractive force and positive dielectrophoresis (PDEP) lateral force on the Y axis. In addition, separation between the two electrodes generates a vertical force along the X axis due to the influence of the vertical repulsive force of negative dielectrophoresis (NDEP). Target or non-target particles are separated at two different locations by using one inlet channel with three outlet channels, left and right channels with PDEP lateral force along the Y axis, and a middle outlet channel with NDEP vertical force along the X axis.

In the description of the present disclosure, it should be noted that the terms “central”, “upper”, “lower”, “left”, “right”, “vertical”, “lateral”, “inner”, “outer”, etc. indicate azimuthal or positional relations based on those shown in the accompanying drawings or the customary azimuthal or positional relations during use of the invention product, and are merely for facilitating description of the present disclosure and for simplifying description, rather than indicating or implying that the referenced device or element must have a particular orientation and be constructed and operative in a particular orientation, and thus may not be construed as a limitation on the present disclosure. In addition, the terms “first”, “second”, “third”, etc. are merely for distinguish between descriptions and may not be understood as indication or implication of relative importance.

In the description of the present disclosure, it should be noted that, unless otherwise explicitly specified and defined, the terms “mounting”, “connecting” and “connection” should be understood in a broad sense, for example, they may be a fixed connection, a detachable connection, or an integrated connection; may be a mechanical connection, or an electrical connection; and may be a direct connection, or an indirect connection via an intermediate medium, or communication inside two elements. For those of ordinarily skilled in the art, specific meanings of the above terms in the present disclosure could be understood according to specific circumstances.

For making the objectives, technical solutions and advantages of the present disclosure clearer, the present disclosure will be further described in detail below in conjunction with the accompanying drawings and examples. It should be understood that the particular examples described herein are merely illustrative of the present disclosure and are not intended to limit the scope of the present disclosure. In addition, in the following specification, the description of the known structure and technique is omitted to avoid unnecessary confusion of the concept of the present disclosure.

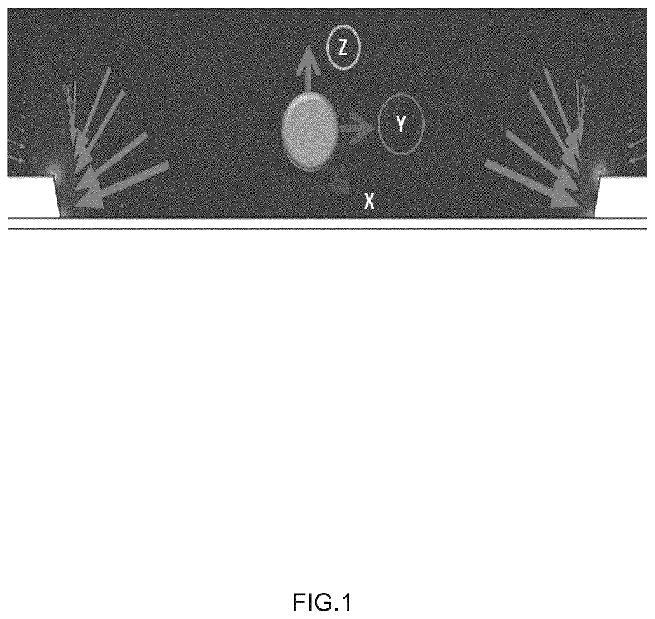

With reference to FIGS. 1-10, which may be used alone or in any combination thereof, and a lateral and vertical dielectrophoresis method for micro/nano-scale biological and metabolic sensors and actuators using two high-intensity electric fields in the present disclosure will be described in more detail with reference to the accompanying drawings.

In one embodiment of the present disclosure, the method includes separating target particles and non-target particles to two different locations, that is, a top electrode surface, and between two tapered electrodes, using a machine, as well as a microfluidic channel at an inlet end, ends of three outlet configurations, a left microfluidic channel, a right microfluidic channel, and a middle microfluidic channel.

The method involves lateral separation of DEP force, where the lateral separation of DEP force is PDEP attractive force between the two tapered electrodes and the top electrode surface along a Y axis, and a separation yield of particles synchronized with lateral motion to terminal ends of electrodes (terminal ends of the left and right microfluidic channels) along an X axis.

The method further includes vertical separation of DEP force, where the vertical separation of DEP force is NDEP repulsive force between the two tapered electrodes and the top electrode surface along the X axis, and a separation yield of particles synchronized with vertical motion (terminal ends of the middle microfluidic channel) along the X axis.

FIGS. 1-7 illustrate working principles of lateral and vertical dielectrophoretic particle separation using points of two higher-intensity electric fields according to an embodiment of the present disclosure.

FIG. 1 illustrates a particle motion plane in a three-dimensional coordinate system, where two-point higher-intensity electric fields are preferably located at bottom and top edges of the tapered electrodes. Therefore, a plurality of descending arrows indicate PDEP attractive force to the two-point high-intensity electric fields on the Y axis in a lateral motion direction. An opposite direction indicates NDEP repulsive force to the two-point high-intensity electric fields on a Z axis in a vertical direction. It should be understood that a direction of capillary fluid flow is along the X axis. It should be noted that all motions in X axis, Y axis and Z axis directions occur simultaneously.

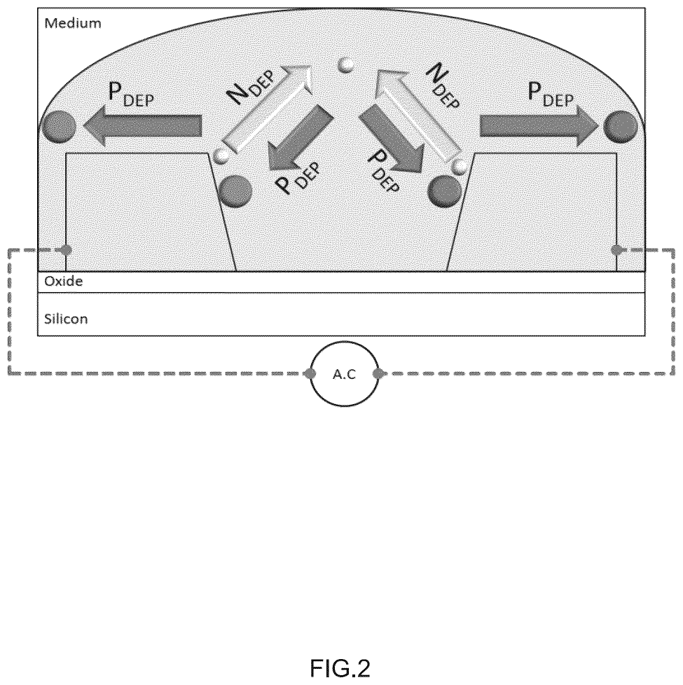

FIG. 2 illustrates a separation mechanism involving the lateral attractive force in the Y axis direction and the vertical repulsive force in the Z axis direction, and pre-lateral and pre-vertical motions of target or non-target particles are shown in FIG. 2.

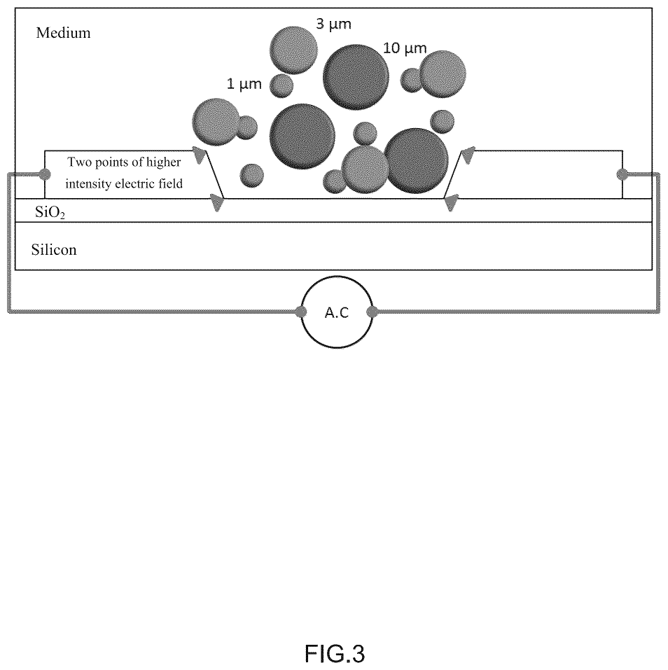

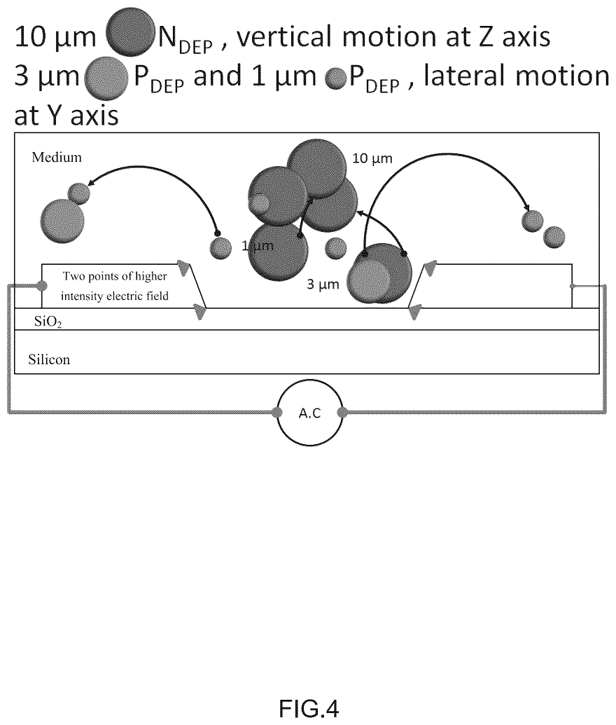

FIGS. 3 and 4 illustrate lateral and vertical motions of target or non-target particles, while lateral and vertical motions of target or non-target particles are shown in FIG. 2.

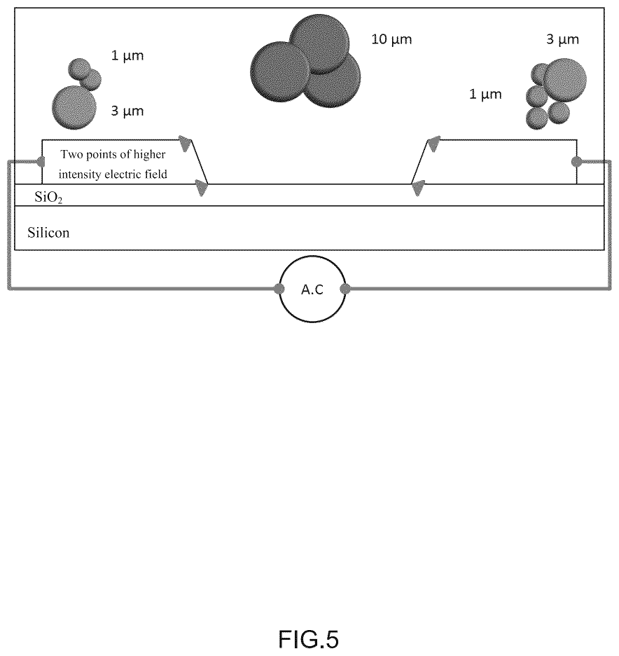

FIG. 5 illustrates lateral and vertical motion columns of target or non-target particles according to a preferred embodiment of the present disclosure.

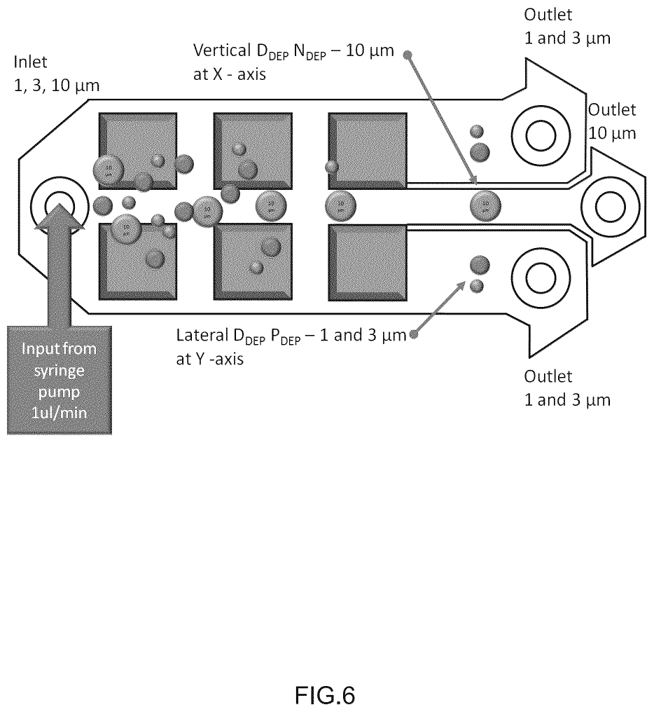

FIG. 6 illustrates integration of microfluidic channel with one inlet microfluidic channel and three outlet microfluidic channels according to a preferred embodiment of the present disclosure. Therefore, yield is collected using capillary force in an X axis flow direction through the one inlet microfluidic channel and the three outlet microfluidic channels.

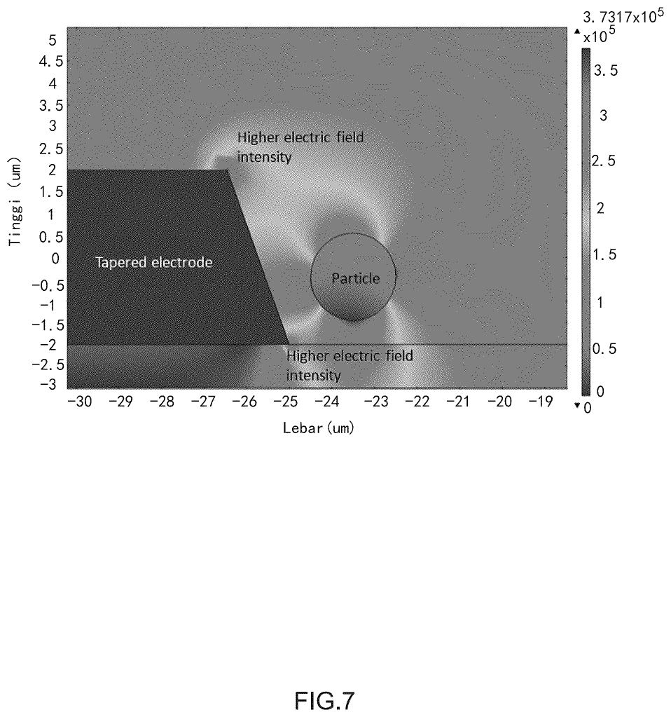

FIG. 7 illustrates two points where particles are exposed to a higher-intensity electric field according to a preferred embodiment of the present disclosure.

In an embodiment of the present disclosure, the present disclosure involves fabricating a microelectrode array of two points of higher-intensity electric field for dielectrophoresis (DEP) based on complementary metal-oxide-semiconductor (CMOS) processing technology, and starting from the deposition of 1.15 μm silicon dioxide (SiO2) on a top of a silicon substrate via plasma-enhanced chemical vapor deposition (PECVD). Then, a thin layer of titanium/titanium nitride (Ti/TiN) with a thickness of 60 nm/30 nm is deposited using physical vapor deposition (PVD) as an adhesion layer. After the Ti/TiN deposition, an aluminum/silicon/copper (Al/Si/Cu) layer with a thickness of at least 4.0 μm is deposited using a preferred ratio of, but not limited to, 98/1/1 wt %. It should be understood that a photoresist thickness of 4.0 μm is applied, including ultraviolet (UV) curing to harden the photoresist and transfer a square array design onto the Al/Si/Cu layer.

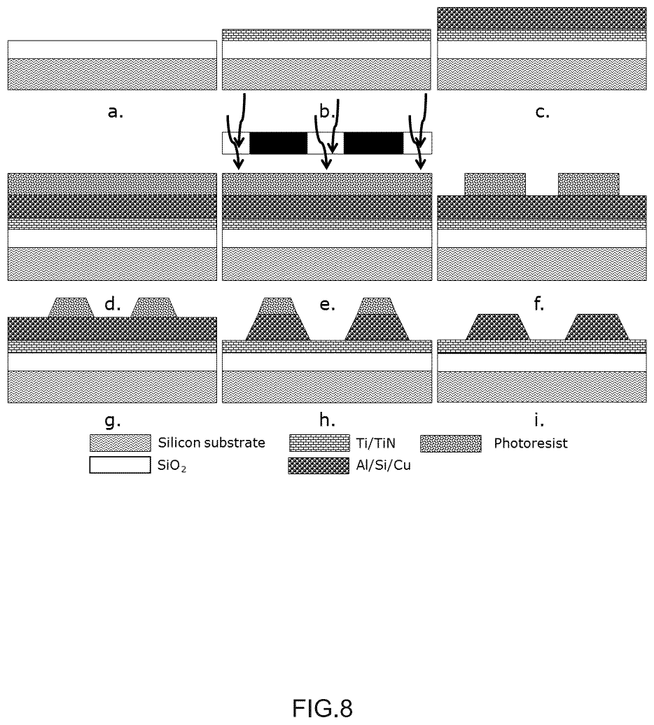

FIGS. 8(a-c) illustrate steps of adding SiO2, Ti/TiN, and Al/Si/Cu.

FIGS. 8(d-f) illustrate photolithography steps of coating, exposure, and

development of a photoresist.

FIGS. 8(g-i) illustrate steps of removing a photoresist profile by lateral etching to achieve photoresist bevel, metal etching, and photoresist removal.

Before a final step of aluminum/silicon/copper etching and after a photolithography process, the following steps are performed to form a resist bevel profile.

In a preferred embodiment, a first step involves resist plasma etching process. Therefore, before a metal etching process, resist plasma etching is adopted to shape a resist profile at a sidewall, such that a profile angle of the microelectrode can be precisely controlled. The photoresist etching at a top of the photoresist sidewall is a technique to smooth the photoresist based on a chemical etching mechanism. It should be understood that various desired resist angles can be achieved by properly controlling parameters such as used gases and ratios thereof, pressure, radio frequency (RF) power, and temperature.

During a fabrication process, a high-pressure baseline formulation includes oxygen (O2), nitrogen (N2), and argon (Ar) in a ratio of 1:4:140, with a pressure of 1600 mT, and an RF power of 1300 W, which is used to produce a pre-designed angle resist. O2 is a primary gas for the resist etching, N2 is a buffer gas to maintain a higher chamber pressure, and Ar is used to increase a plasma density. It should be noted that etching time modification greatly affects an angle of the photoresist profile and is used to modify the photoresist profile. The photoresist profile can be replicated in the metal etching process.

Further, the metal etching process is performed, the system configuration and gas

composition are specified for anisotropic etching based on chemical and physical etching mechanisms. For the metal etching process, a baseline instruction includes chlorine (Cl2), boron trichloride (BCl3), and argon (Ar), with a preferred ratio of, but not limited to, 1:0.4:0.2, a pressure of 8 mT, a source power of preferably 1200 W, and a bias power of preferably 175 W. Therefore, Cl2 is a chlorine-based gas, which is used for primary gas of plasma-free aluminum etching. In addition, Cl2 is also a main etchant for the resist. Excessive Cl2 in chemical reaction results in a low selective etching rate between the aluminum and the resist.

It should be noted that the metal etching process is a most challenging step in CMOS standard technology. Therefore, BCl3 is a heavy molecule used for physical bombardment, while Ar is mainly used for removing residue. An inductively coupled plasma (ICP) process based on chemical and physical etching mechanisms is introduced. In order to control etching quality, new four-step etching technique conditions are introduced. Therefore, a first step of etching is breakthrough etching (BE) controlled by time. A second step is main etching (ME) controlled by endpoint detection. Third and fourth steps are over-etching (OE) and residue removal etching (RRE), both of which are controlled by time of the etching process. It should be understood that the BE is performed to remove native oxide and resist residues left after a photolithography process, and the ME is performed to remove bulk aluminum. The OE and RRE are performed to remove residual aluminum on thicker areas of aluminum and to remove aluminum residues. It should be understood that timing of BE, OE, and RRE is selected on the basis of visual inspection through a microscope for color monitoring, a critical dimension scanning electron microscope (CDSEM) for critical dimension measurement, and a field emission scanning electron microscope (FESEM) for cross-sectional views.

After an etching process instruction is established, a last step of etching process monitoring is to measure a remaining thickness of silicon dioxide (SiO2). By using an aluminum etching formulation, the selectivity of aluminum and the resist is preferably 1:1 based on an etching rate test of each material. The lateral etching of a resist bevel process produces a resist angle of approximately 16 degrees.

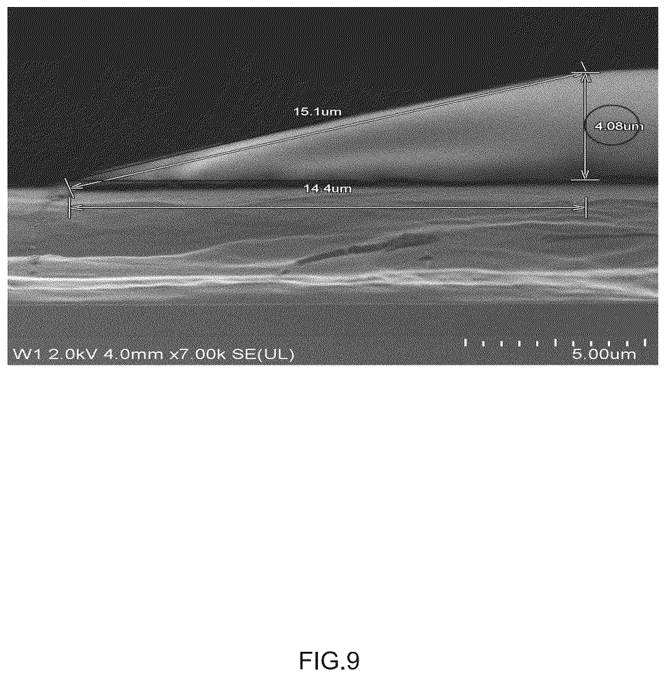

FIG. 9 illustrates a photoresist of tapered profile before the metal etching process. After the aluminum etching process, an aluminum tilt angle of approximately 65-70 degrees is obtained as the resist angle.

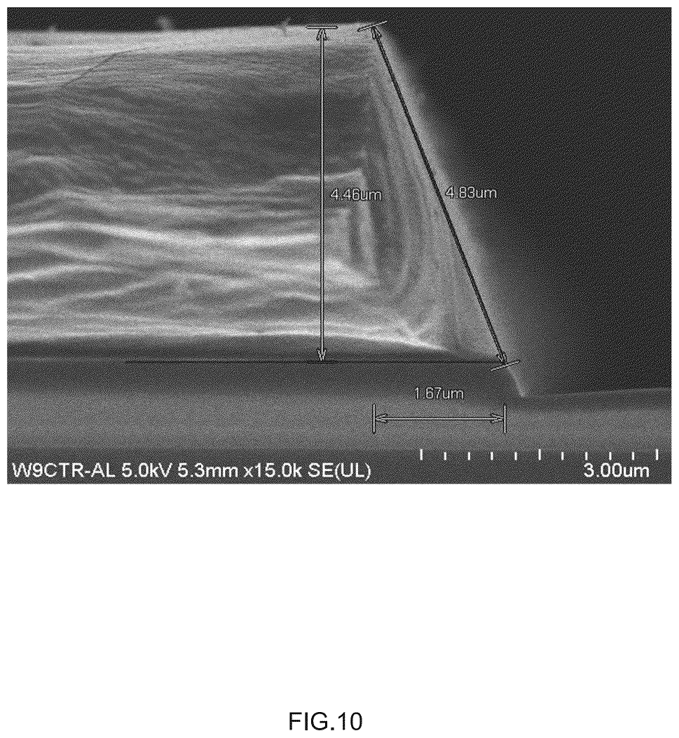

FIG. 10 clearly illustrates a tapered profile dielectrophoresis microelectrode.

In an embodiment of the present disclosure, two points of a high-intensity electric field with a sidewall profile angle of 20° produce a higher electric field gradient from the top and bottom edges of the microelectrode based on field analysis and experimental work, such that more efficient operation, separation and fractionation can be achieved in the medium in both the lateral and vertical directions. Engineered particles with three different diameters are subjected to test. Test results indicate that first 3 minutes with a slowest flow rate are considered to show the impact of force of dielectric polarization (FDEP) on various particles, with a purpose of capturing 10 μm particles in a region between the microelectrodes, and releasing 1 μm and 3 μm particles from the region. By selecting an appropriate frequency between crossover frequencies for 10 μm engineered particles and other particles, DEP force can be applied to drive the particles and capture desired particles. The crossover frequency (fxo) for 10 μm particles is about 25 kHz, and the crossover frequencies for 3 μm and 1 μm particles are 380 kHz and 1315 kHz, respectively. Therefore, a DEP signal frequency of 200 kHz is selected for the 10 μm isolation experiment. At the frequency, 10 μm particles are subjected to the NDEP repulsive force in the vertical direction of the Z axis, and other particles are subjected to the PDEP attractive force in the lateral direction of the Y axis. Therefore, 1 μm and 3 μm particles are attracted to a highest electric field region at the top electrode surface, and 10 μm particles are repelled from highest electric field regions on the left and right sides of the two higher-intensity electric field profile electrodes.

It should be understood that the dielectrophoresis microelectrodes of two-point higher-intensity electric field with a new profile can be applied in a lab-on-chip of an active filtration system, such as application for circulating tumor cells and renal albumin filtration (artificial kidney). Therefore, application of the dielectrophoresis microelectrodes of two-point higher-intensity electric field in the lab-on-chip could probably eliminate related traditional designs, such as dielectrophoresis microelectrodes of the lateral single-point high-intensity electric field, labeling techniques, biomarkers, and passive filters (such as pore filters).

It should be further understood that the dielectrophoresis microelectrodes of two-point higher-intensity electric field can be applied in biomedical and bio-MEMS systems, such as prognosis of circulating tumor cells (CTC) or and renal albumin filtration (artificial kidney). The miniaturization of the fabrication process for the dielectrophoresis microelectrodes of two-point higher-intensity electric field has been implemented in the lab-on-chip system. the dielectrophoresis microelectrodes of two-point higher-intensity electric field in the lab-on-chip system are more compact, reliable, and easier to operate.

Working principles and specific process of the method in the present disclosure are as follows:

The dielectrophoresis microelectrode provides a multifunctional platform for manipulating, separating, and characterizing various biological entities, including cells, bacteria, protein, viruses, and metabolites.

The method involves performing resist plasma etching before metal etching to form a resist profile at the sidewall, where a high-pressure baseline formulation includes oxygen (O2), nitrogen (N2), and argon (Ar) in a ratio of 1:4:140, with a pressure of 1600 mT, and an RF power of 1300 W, which is used to produce a pre-designed angle resist; and

performing the metal etching, where a baseline instruction includes chlorine (Cl2), boron trichloride (BCl3), and argon (Ar), with a preferred ratio of, but not limited to, 1:0.4:0.2, a pressure of 8 mT, a source power of preferably 1200 W, and a bias power of preferably 175 W;

measure a remaining thickness of silicon dioxide (SiO2);

where an inductively coupled plasma (ICP) process based on chemical and physical etching mechanisms is introduced, and new four-step etching technique conditions are introduced to control etching quality;

where the four-step etching technique conditions include:

breakthrough etching (BE) controlled by time; main etching (ME) controlled by endpoint detection; over-etching (OE) controlled by time of the etching process; and residue removal etching (RRE) controlled by time of the etching process; and

the two-point higher-intensity electric fields provide separation and fractionation of target and non-target particles in a medium through the PDEP attractive force on the Y axis and the NDEP repulsive force on the Z axis, and collects the flow of one inlet microfluidic channel with three outlet microfluidic channels using capillary force on the X axis.

It should be noted that although the examples mentioned above have been described herein, they do not therefore limit the patent protection scope of the present invention. Therefore, based on the innovative ideas of the present disclosure, variations and modifications made on the examples of the description, or equivalent structure, equivalent process or equivalent function change made by using contents of the description and the accompanying drawings in the present disclosure and used directly or indirectly in other related technical fields shall all fall within the protection scope of the present disclosure.

### INDUSTRIAL APPLICABILITY

It should be noted that the present disclosure demonstrates that a concept of two higher-intensity electric fields can be further explored for transporting, accumulating, separating and characterizing micro/nano-scale particles. Particles can be manipulated, separated, and fractionated in both lateral and vertical directions using the dielectrophoresis microelectrodes of the higher-intensity electric field at two points. Compared with the dielectrophoresis microelectrodes of single-point conventional high-intensity electric field, particles can be manipulated, separated and fractionated in the vertical direction. The present disclosure can improve non-contact operation methods, offering high sensitivity, high selectivity, and label-free detection of target particles for application analysis specifications.

It should be noted that for the application in the dielectrophoresis microelectrodes of two-point higher-intensity electric field, the present disclosure can achieve improved process operation, separation, and fractionation performance with higher efficiency greater than 90%. Therefore, the electrode profile of two-point higher-intensity electric field is preferably adopted due to the advantages of particle motion in both the lateral and vertical directions under the influence of PDEP and NDEP in the force of dielectrophoresis microelectrode (FDEP). In terms of an active filter, the dielectrophoresis microelectrodes of two-point higher-intensity electric field serve as non-contact filters with self-cleaning capabilities, without affecting process operation, separation, or fractionation, and reaching efficiency greater than 90%. The dielectrophoresis microelectrode profile of two-point higher-intensity electric field is selected due to its ability to achieve process operation, separation, and fractionation with efficiency greater than 90% efficiency, making it beneficial for biomedical devices, such as the prognosis of circulating tumor cells or renal albumin filtration.

What is claimed is:

1. A lateral and vertical dielectrophoresis method for micro/nano-scale biological and metabolic sensors and actuators using two high-intensity electric fields, comprising the following steps:
S1. performing resist plasma etching before metal etching to form a resist profile at a sidewall, wherein a high-pressure baseline formulation comprises oxygen, nitrogen and argon in a ratio of 1:4:140, with a pressure of 1600 mT, and an RF power of 1300 W, which is used to produce a pre-designed angle resist;
S2. performing the metal etching, wherein a baseline instruction comprises chlorine, boron trichloride and argon, with a preferred ratio of, but not limited to, 1:0.4:0.2, a pressure of 8 mT, a source power of preferably 1200 W, and a bias power of preferably 175 W; and
S3. performing metal profiling measurement to measure a remaining thickness; wherein
an inductively coupled plasma process based on chemical and physical etching mechanisms is introduced, and new four-step etching technique conditions are introduced to control etching quality;
the four-step etching technique conditions comprise:
breakthrough etching controlled by time;
main etching controlled by endpoint detection;
over-etching controlled by time of an etching process; and
residue removal etching controlled by the time of an etching process.

2. The lateral and vertical dielectrophoresis method for micro/nano-scale biological and metabolic sensors and actuators using two high-intensity electric fields according to claim 1, wherein the oxygen is a primary gas for resist etching, the nitrogen is a buffer gas to maintain a higher chamber pressure, and the argon is used to increase a plasma density.

3. The lateral and vertical dielectrophoresis method for micro/nano-scale biological and metabolic sensors and actuators using two high-intensity electric fields according to claim 1, wherein the chlorine is a chlorine-based gas and is used as a primary etchant for plasma-free aluminum.

4. The lateral and vertical dielectrophoresis method for micro/nano-scale biological and metabolic sensors and actuators using two high-intensity electric fields according to claim 1, wherein the breakthrough etching is performed to remove native oxide and resist residues left after a photolithography process.

5. The lateral and vertical dielectrophoresis method for micro/nano-scale biological and metabolic sensors and actuators using two high-intensity electric fields according to claim 1, wherein the main etching is performed to remove bulk aluminum.

6. The lateral and vertical dielectrophoresis method for micro/nano-scale biological and metabolic sensors and actuators using two high-intensity electric fields according to claim 1, wherein the over-etching and the residue removal etching are performed to remove residual aluminum on thicker areas of aluminum and to remove aluminum residues.

7. The lateral and vertical dielectrophoresis method for micro/nano-scale biological and metabolic sensors and actuators using two high-intensity electric fields according to claim 1, wherein timing of the breakthrough etching, the over-etching and the residue removal etching is selected on the basis of visual inspection through a microscope for color monitoring, a critical dimension scanning electron microscope for critical dimension measurement, and a field emission scanning electron microscope for cross-sectional views.

8. The lateral and vertical dielectrophoresis method for micro/nano-scale biological and metabolic sensors and actuators using two high-intensity electric fields according to claim 1, wherein the method further uses a microfluidic channel with one inlet end and three outlet ends to separate target particles and non-target particles to two different locations, that is, a top electrode surface, and between two tapered electrodes.

9. The lateral and vertical dielectrophoresis method for micro/nano-scale biological and metabolic sensors and actuators using two high-intensity electric fields according to claim 1, wherein the method involves lateral separation of dielectrophoresis (DEP) force, the lateral separation of DEP force is positive DEP (PDEP) attractive force between the two tapered electrodes and the top electrode surface along a Y axis, and a separation yield of particles having lateral motion to terminal ends of electrodes in synchronization with a capillary of an X axis.

10. The lateral and vertical dielectrophoresis method for micro/nano-scale biological and metabolic sensors and actuators using two high-intensity electric fields according to claim 1, wherein the method further comprises vertical separation of DEP force, the vertical separation of DEP force is negative DEP (NDEP) repulsive force from the top electrode surface to the two tapered electrodes along the X axis, and a separation yield of particles having vertical motion in synchronization with the capillary of the X axis.
